(19) United States
(12) Patent Application Publication
(10) Pub. No.: US 2023/0002238 A1
(43) Pub. Date: Jan. 5, 2023

(54) APPARATUS FOR MANUFACTURING POLYSILICON ROD AND METHOD FOR MANUFACTURING POLYSILICON ROD

(71) Applicant: Shin-Etsu Chemical Co., Ltd., Tokyo (JP)

(72) Inventors: Naruhiro HOSHINO, Niigata (JP); Tetsuro OKADA, Niigata (JP); Masahiko ISHIDA, Niigata (JP)

(73) Assignee: Shin-Etsu Chemical Co., Ltd., Tokyo (JP)

(21) Appl. No.: 17/851,637

(22) Filed: Jun. 28, 2022

(30) Foreign Application Priority Data
Jul. 5, 2021 (JP) 2021-111400

(51) Int. Cl. C01B 33/035; C23C 16/24; C23C 16/54

(52) U.S. Cl. CPC C01B 33/035; C23C 16/24; C23C 16/545

(57) ABSTRACT

An apparatus for manufacturing a polysilicon rod comprising: a core wire 1 on which polysilicon is deposited; a core wire electrode 60 provided to penetrate a bottom plate 80; an adjustment member 10 provided between the silicon core wire 1 and the core wire electrode 60, and movable with respect to the bottom plate 80; and a cooling part capable of cooling the adjustment member 10.

### TECHNICAL FIELD

The present invention relates to an apparatus for manufacturing polysilicon and a method for manufacturing polysilicon for depositing polysilicon by supplying a source gas to a surface of a heated silicon core wire.

The present application claims the priority of Japanese Patent Application No. 2021-111400 filed on Jul. 5, 2021, the contents of which are entirely incorporated by reference.

### BACKGROUND ART

Polysilicon is a raw material of monosilicon for semiconductor or silicon for solar cell. As a method for manufacturing polysilicon, a Siemens method is known. The Siemens method is a method in which a silane source gas is generally brought into contact with a heated silicon core wire to deposit polysilicon on the surface of the silicon core wire using a chemical vapor deposition (CVD) method.

In the Siemens method, two silicon core wires in a vertical direction and one silicon in a horizontal direction are assembled in an inverted U-shape, and both end parts of the inverted U-shaped silicon core wire are connected to respective core wire holders and fixed to a pair of metal electrodes disposed on a bottom plate. In general, a plurality of sets of inverted U-shaped silicon core wires is disposed in the reaction furnace.

An inverted U-shaped silicon core wire is heated to a deposition temperature by energization, a mixed gas of, for example, trichlorosilane and hydrogen is brought into contact with the silicon core wire as a source gas, and silicon is vapor-grown to form a polysilicon rod having a desired diameter in an inverted U-shape.

In the bottom plate used in the Siemens method, the silicon core wire electrode is generally inserted into the through hole of the bottom plate of the reaction furnace. Since a plurality of sets of silicon core wires is disposed as described above, there is a plurality of silicon core wire electrodes penetrating the bottom plate.

Under such circumstances, various proposals have been made on the arrangement of electrodes.

Patent Document 1 (JP 2011-231005 A) proposes a positional relationship between a silicon core rod, a source gas supply port, and an exhaust port in order to provide a polysilicon reduction furnace in which polysilicon can be easily deposited so as not to have a surface shape defect or warpage.

Patent Document 2 (WO 2011/123998 A) proposes an arrangement capable of increasing thermal efficiency and uniformity of a gas flow to increase a production amount, improve surface quality, and reduce energy consumption.

Also in Patent Document 3 (WO 2012/171149 A) and Patent Document 4 (WO 2013/093051 A) propose an arrangement in a reaction furnace for the purpose of productivity and uniformity in the reaction furnace.

Under such circumstances, Patent Document 5 (JP 2014-101256 A) proposes to make the arrangement variable in order to extend the life of the heater installed in the furnace.

### SUMMARY OF INVENTION

### Problem to be Solved by Invention

However, the optimal arrangements proposed in Patent Documents 1 to 4 are different from each other. In addition, an increase in size of the reaction furnace is also progressing, and the cost for the reactor is very large. Nevertheless, it is necessary to determine the arrangement of the silicon core wire electrodes penetrating the bottom plate before installation.

However, in practice, the growth shape of the polysilicon cannot be known unless the polysilicon is grown in the installed reactor itself.

In addition, an aspect as in Document 5 is also proposed, but even when the arrangement of the heater can be optimized by Document 5, the arrangement of the core wire cannot be readjusted because the polysilicon is deposited on the adapter or the like, and the adapter or the like itself is difficult to reuse and has to be discarded. Even when it can be reused, the deposited polysilicon may be peeled off from the adjustment member at the time of readjustment of the arrangement. The polysilicon deposited on the adapter or the like is in contact with the member, and the quality is deteriorated. The polysilicon falls into the furnace, and as a result, contamination in the furnace increases. In addition, since the deposited polysilicon is not suitable as polysilicon for semiconductors or solar cells, it has to be allocated to products with low quality requirements.

The present invention has been made in view of such a problem, and an object of the present invention is to provide an apparatus for manufacturing a polysilicon rod and a method for manufacturing a polysilicon rod capable of suppressing deposition of silicon on an adapter or the like, and moving the position of a core wire electrode without any trouble.

### Means for Solving Problem

### [Concept 1]

An apparatus for manufacturing a polysilicon rod in the present invention may comprise:

a core wire on which polysilicon is deposited;

a core wire electrode provided to penetrate a bottom plate;

an adjustment member provided between the silicon core wire and the core wire electrode, and movable with respect to the bottom plate; and

a cooling part capable of cooling the adjustment member.

### [Concept 2]

In the apparatus for manufacturing a polysilicon rod according to concept 1, the cooling part may have a nozzle that blows gas toward the adjustment member.

### [Concept 3]

In the apparatus for manufacturing a polysilicon rod according to concept 2, the gas may be a silane source gas.

### [Concept 4]

In the apparatus for manufacturing a polysilicon rod according to any one of concepts 1 to 3, the cooling part may have a heat dissipation insulating member provided between the bottom plate and the adjustment member and configured to cool the adjustment member via the bottom plate.

### [Concept 5]

In the apparatus for manufacturing a polysilicon rod according to any one of concepts 1 to 4, the cooling part may be provided in the core wire electrode and has a flow path through which a coolant flows.

### [Concept 6]

In the apparatus for manufacturing a polysilicon rod according to any one of concepts 1 to 5, the adjustment member may connect the core wire electrode and the silicon core wire so that a central axis of the core wire electrode is different from a central axis of the silicon core wire.

### [Concept 7]

In the apparatus for manufacturing a polysilicon rod according to any one of concepts 1 to 6, the adjustment member may be made of a material different from a material of the core wire electrode.

### [Concept 8]

In the apparatus for manufacturing a polysilicon rod according to any one of concepts 1 to 7, the adjustment member may have a resistivity lower than a resistivity of the core wire electrode.

### [Concept 10]

A method for manufacturing a polysilicon rod using the apparatus for manufacturing a polysilicon rod according to any one of concepts 1 to 8, the method may comprise

a step of depositing the polysilicon on the core wire,

wherein the step of depositing the polysilicon may include cooling an adjustment member by the cooling part.

By applying the present invention to an apparatus or a method for growing a polysilicon rod, the position of the silicon core wire electrode can be smoothly moved, and the arrangement can be optimized.

By adopting the mechanism and the member for cooling the adjustment member as an aspect of the present invention, the adjustment member can be cooled at the time of manufacturing the polysilicon, so that the deposition of the polysilicon on the adjustment member can be prevented and the movement of the adjustment member is not hindered. As a result, when the adjustment member moves without any trouble, the stress applied to the core wire electrode by the polysilicon during the growth or the post-manufacturing cooling can be relaxed, and the cracking and collapse of the polysilicon during the growth or the post-manufacturing cooling can be prevented.

### BRIEF DESCRIPTION OF DRAWINGS

FIG. 1 is a longitudinal sectional view of a reaction furnace according to an embodiment of the present invention;

FIG. 2 is a plan view of a silicon core wire, an adjustment member, and the like used in the embodiment of the present invention when viewed from above;

FIG. 3 is a plan view illustrating a state in which they are rotated around a central axis of the silicon core wire electrode from the state of FIG. 2;

FIG. 4 is a longitudinal sectional view illustrating an example of an adjustment member used in the embodiment of the present invention;

FIG. 5 is a longitudinal sectional view illustrating an example of a mechanism for cooling an adjustment member used in the embodiment of the present invention;

FIG. 6 is a longitudinal sectional view showing another example of a mechanism for cooling an adjustment member used in the embodiment of the present invention;

FIG. 7 is a longitudinal sectional view illustrating a mechanism for moving an adjustment member used in the embodiment of the present invention, and illustrates an aspect which is different from aspects illustrated in FIGS. 2 to 4; and

FIG. 8 is a longitudinal sectional view illustrating a mechanism for cooling an adjustment member, a control unit, and a thermometer used in the embodiment of the present invention.

### DETAILED DESCRIPTION

Hereinafter, embodiments for carrying out the present invention will be described.

### <Configuration>

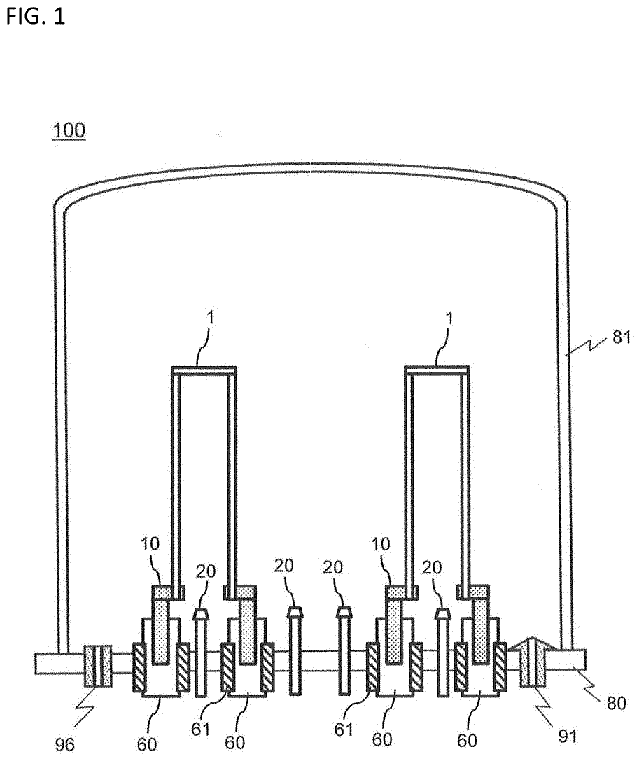

As shown in FIG. 1, a reaction furnace 100 used in the Siemens method has a bottom plate (base plate) 80 and a bell jar 81. A silicon core wire electrode 60 is generally inserted into a through hole of the bottom plate 80 of the reaction furnace 100. In general, since a plurality of sets of silicon core wires 1 is disposed, there is a plurality of silicon core wire electrodes 60 penetrating the bottom plate 80.

Therefore, the position of the through hole of the bottom plate 80 is required to be determined at the time of designing the reaction furnace 100. However, in practice, the growth shape of the polysilicon cannot be known unless the polysilicon is grown in the installed reaction furnace 100 itself.

When the reaction furnace 100 is added under exactly the same conditions, there is no big problem. However, in many cases, an improved reaction furnace 100 is designed for the purpose of improving the shape of popcorn, which is a type of productivity and surface shape, the shape of polysilicon during growth, and the like. At this time, in the disposition in the reaction furnace 100, not only the disposition of the silicon core wire electrode 60 but also the disposition of a supply gas inlet 91 and an exhaust gas outlet 96 in the furnace are often changed. In the reaction conditions, the temperature, the supply gas concentration, the supply gas flow rate, the reaction pressure, and the like are often changed together. In this case, since the arrangement is changed and the reaction conditions are changed, in practice, the growth shape of the polysilicon including the popcorn shape is not known unless the polysilicon is grown in the installed reaction furnace 100 itself.

In addition, as shown in Patent Document 5, even when the arrangement of only the heater can be optimized, since the heater is used for initial heating and the heater stops energization while the polysilicon is growing, there is almost no deposition of the polysilicon on the heater. For this reason, Patent Document 5 may be used to adjust only the position of the heater before the polysilicon is deposited, but there may be a problem in moving the arrangement of the silicon core wire 1 after the polysilicon is deposited.

Therefore, care for preventing deposition of polysilicon on the moving member is required in a case where the arrangement of the silicon core wire 1 moves on the bottom plate 80 when the silicon core wire 1 is energized in a state where the reaction gas is supplied and the reaction temperature is reached, or at the time of cooling after completion of the reaction.

In the present embodiment, it is possible to freely dispose the silicon core wire 1 above the bottom plate 80 without being affected by the position of the through hole of the silicon core wire electrode 60. In this case, the adjustment can be made above the bottom plate 80.

As an example, the apparatus for manufacturing a polysilicon rod according to the present embodiment is an apparatus for manufacturing a polysilicon rod by the Siemens method. As illustrated in FIG. 1, the apparatus for manufacturing a polysilicon rod has a silicon core wire (core wire) 1 on which polysilicon is deposited, a silicon core wire electrode (core wire electrode) 60 provided to penetrate a bottom plate 80, an adjustment member 10 provided between the silicon core wire 1 and the silicon core wire electrode 60 and including an adapter or the like movable with respect to the bottom plate 80, and a cooling part (cooling mechanism) capable of cooling the adjustment member 10.

In order to relax the stress when the diameter of the polysilicon increases during the reaction or when the polysilicon rod is cooled at the end of the reaction, the adjustment member 10 naturally moves in the plane. As the diameter of the grown polysilicon increases, the amount of movement of the adjustment member 10 that moves during the reaction, the cooling, or the reaction and the cooling increases. When the average diameter of the polysilicon in the reaction furnace was 150 mm, the amount of movement of the adjustment member 10 was 10 mm at the maximum. Similarly, when the polysilicon diameter was 120 mm, the amount of movement was 7 mm at the maximum.

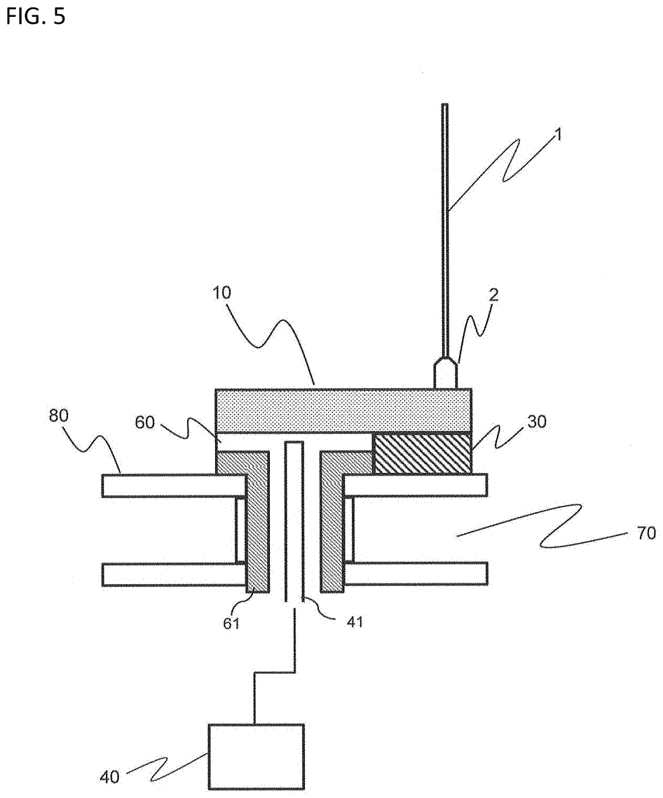

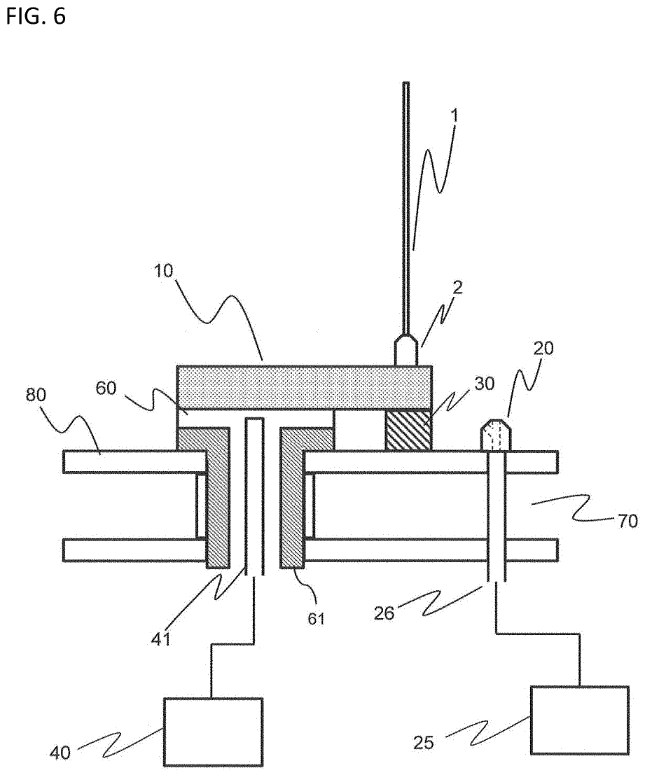

The adjustment member 10 such as an adapter may be connected on the bottom plate 80 so that the central axis of the silicon core wire electrode 60 is different from the central axis of the silicon core wire 1. A core wire holding member 2 may be provided between the adjustment member 10 and the silicon core wire 1 (see FIGS. 5 and 6).

As illustrated in FIG. 1, both lower end parts of the silicon core wire 1 having an inverted U shape are fixed to the pair of silicon core wire electrodes 60 via the adjustment member 10. The silicon core wire electrode 60 penetrates the bottom plate 80 with an insulator 61 interposed therebetween.

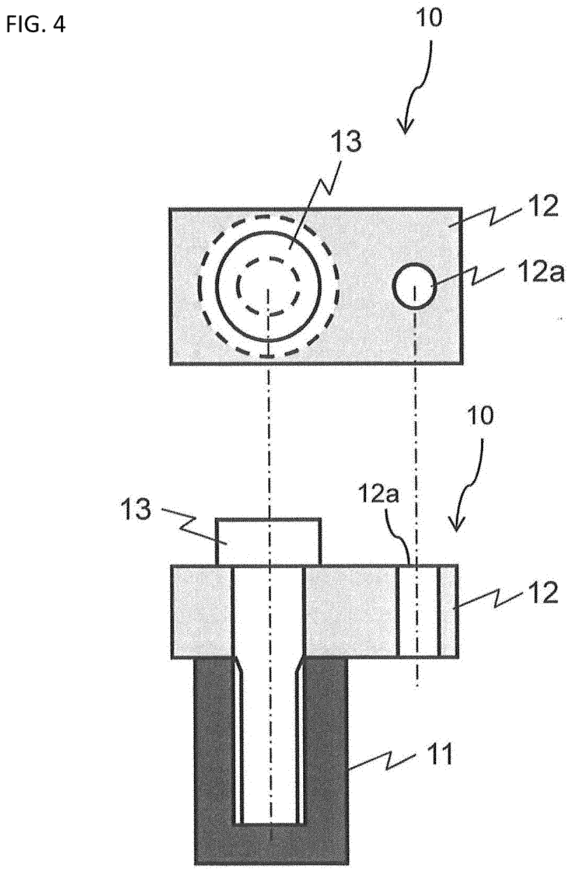

As illustrated in FIG. 4, the adjustment member 10 may include an electrode coupling member 11 having a recess at the center, a holding member 12 that holds the lower end part of the silicon core wire 1 and is rotatable around the central axis of the electrode coupling member 11, and a fastening member 13 such as a screw that is inserted into the recess of the electrode coupling member 11 to support the holding member 12. The lower end part of the silicon core wire 1 may be fixed in such a manner as to be inserted into a hole part 12a provided in the holding member 12.

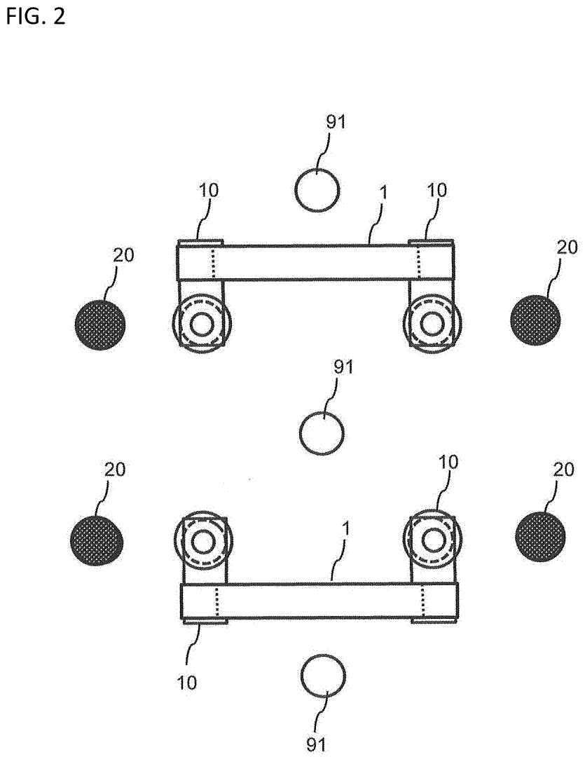

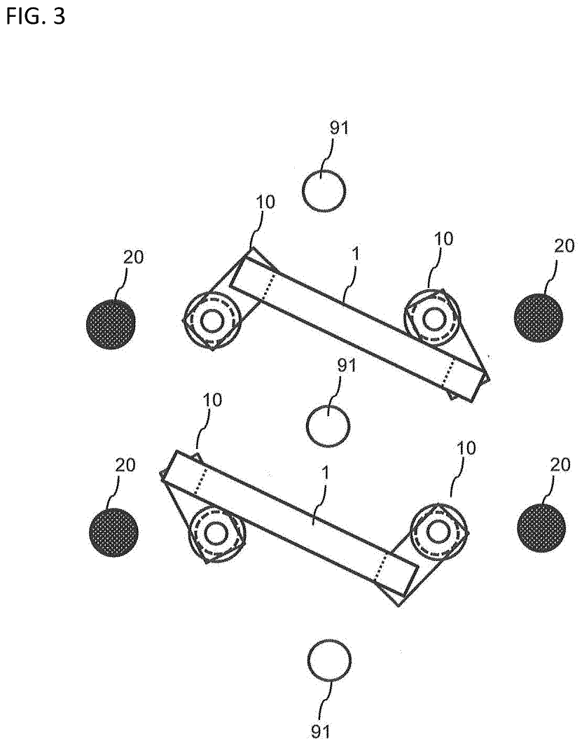

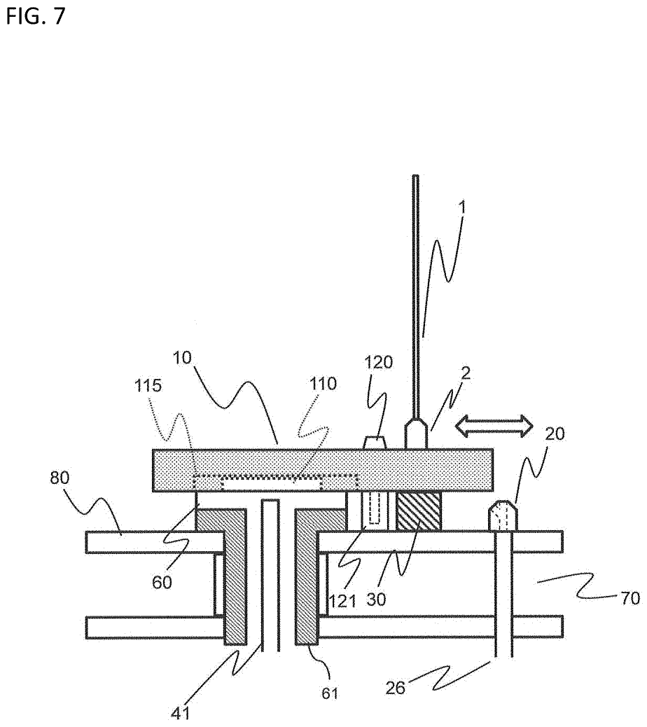

FIG. 2 is a diagram illustrating a state in which both lower end parts of the silicon core wire 1 are held by a pair of adjustment members 10 of the silicon core wire 1 when viewed from the upper direction of the bottom plate 80, and this diagram illustrates an aspect in which two silicon core wires 1 are provided. FIG. 2 illustrates an aspect in which a cooling nozzle 20 to be described later is provided adjacent to each of both lower end parts of the silicon core wire 1. FIG. 3 illustrates an aspect in which the adjustment member 10 in the state of FIG. 2 is rotated around the central axis of the silicon core wire electrode 60. As described above, both lower end parts of the silicon core wire 1 of the present embodiment are movable. There are various aspects of moving both lower end parts of the silicon core wire 1, and for example, both lower end parts of the silicon core wire 1 may be moved by sliding in an in-plane direction (horizontal direction) (see FIG. 7). In this case, for example, a recess 115 may be provided at the bottom face of the adjustment member 10, and a protrusion 110 to be inserted into the recess 115 may be provided on the upper face of the core wire electrode 60. Then, the adjustment member 10 may be movable along the protrusion 110, and the position thereof may be fixed to a fixture 121 fixed to the bottom plate 80 by the fastening member 120.

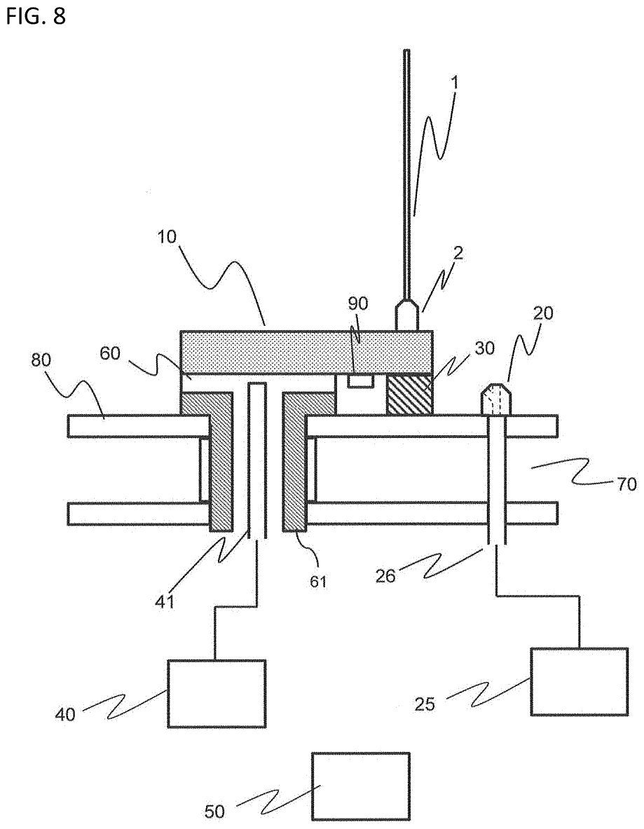

As illustrated in FIG. 6, the cooling part may have a gas supply unit 25 that supplies the stored gas or the generated gas, a nozzle (cooling nozzle) 20 that blows the gas toward the adjustment member 10, and a gas supply pipe 26 that is provided between the gas supply unit 25 and the nozzle 20 and guides the gas supplied from the gas supply unit 25 to the nozzle 20. The gas supplied from the gas supply unit 25 may be a silane source gas. In this case, the silane source gas may be, for example, a mixed gas of trichlorosilane and hydrogen. Since the movement distance of the adjustment member 10 due to the stress generation during the deposition reaction of the polysilicon and/or during the cooling of the polysilicon rod is about 10 nu, the adjustment member 10 can be sufficiently cooled even when the position of the nozzle 20 is fixed. However, the present invention is not limited to such an aspect, and the position of the nozzle 20 may be movable in the in-plane direction by sliding or the like. In addition, the supply amount of gas from the gas supply unit 25 and/or the direction of the nozzle 20 can be freely changed, and even when the adjustment member 10 moves due to stress generation during the deposition reaction of the polysilicon and/or during cooling of the polysilicon rod, sufficient cooling may be performed on the adjustment member 10 by adjusting the supply amount of gas and the direction of the nozzle 20. The control of each member at this time may be performed in response to a command from a control unit 50 (see FIG. 8).

As illustrated in FIGS. 5 and 6, the cooling part may include a heat dissipation insulating member 30 provided between the bottom plate 80 and the adjustment member 10 to cool the adjustment member 10 via the bottom plate 80. A bottom plate coolant passage 70 through which a coolant such as cooling water passes may be provided inside the bottom plate 80, and the bottom plate 80 may be cooled by the coolant passing through the bottom plate coolant passage 70. By providing the heat dissipation insulating member 30 described above, the adjustment member 10 can be cooled by the cooled bottom plate 80. Silicon rubber or the like blended with a thermally conductive filler may be used for the heat dissipation insulating member 30. For example, an insulating composition obtained by blending 100 to 800 parts by weight of at least one metal oxide selected from beryllium oxide, aluminum oxide, hydrated aluminum oxide, magnesium oxide, and zinc oxide into 100 parts by weight of synthetic rubber such as silicon rubber may be used. Furthermore, ceramics may be used. As another example of the heat dissipation insulating member 30, for example, silicon nitride, silicon carbide, aluminum nitride, aluminum oxide, zirconia, or the like may be used. When the core wire electrode 60 is made of copper, the thermal conductivity is very high. When the cooling water flows in the core wire electrode 60, the heat dissipation insulating member 30 can be cooled by the core wire electrode 60, and as a result, the adjustment member 10 can be cooled.

The heat dissipation insulating member 30 may be fixed to the adjustment member 10 and not fixed to the bottom plate 80. In this case, the heat dissipation insulating member 30 also moves with the movement of the adjustment member 10. When the heat dissipation insulating member 30 has a sufficient large size in the in-plane direction (horizontal direction) with respect to the movable distance of the adjustment member 10, the heat dissipation insulating member 30 may be fixed to the bottom plate 80, and the bottom plate 80 does not move even when the adjustment member 10 moves within a range of about 10 mm. As an example, when the adjustment member 10 moves by about 10 mm during the deposition reaction of the polysilicon and/or during the cooling of the polysilicon rod, even when the size of the heat dissipation insulating member 30 in the in-plane direction is not so large, the adjustment member 10 and the bottom plate 80 can be always brought into contact with each other via the heat dissipation insulating member 30 regardless of the position of the adjustment member 10.

As illustrated in FIGS. 5 and 6, the cooling part may have a liquid supply unit 40 that supplies a coolant such as cooling water, and an electrode coolant flow path 41 that is provided in the core wire electrode 60 and allows the coolant to flow. The core wire electrode 60 is preferably configured so that a coolant such as cooling water normally flows in order to cool the energized electrode.

As described above, by adopting, as the cooling part, any one or more or all of the mechanism that blows the cooling gas toward the adjustment member 10, the mechanism that cools the adjustment member 10 by the heat dissipation effect by connecting the adjustment member to the bottom plate 80 via the heat dissipation insulating member 30, and the mechanism that cools the adjustment member 10 via the core wire electrode 60 by the coolant, it is possible to prevent the deposition of the silicon crystal on the adjustment member 10. That is, when the cooling part (cooling mechanism) is not provided, silicon crystals may deposit on the adjustment member 10 due to heat generation by energization or the like. When the silicon crystal is deposited on the adjustment member 10 in this manner, in a case where the position of the adjustment member 10 is adjusted and moved before the start of the growth of next polysilicon (new polysilicon), the crystal deposited during the movement falls into the furnace, resulting in contamination. In addition, when silicon crystals are deposited on the adjustment member 10 in this manner, there may be a problem that adjustment by the adjustment member 10 cannot be performed smoothly. In this respect, adopting the cooling part as described above is very advantageous in that heat generation due to energization in the adjustment member 10 can be removed, and occurrence of such a problem can be prevented in advance. According to the present aspect, it is also possible to prevent the resistance value of the adjustment member 10 from increasing due to heat generation.

In addition, since the adjustment member can be cooled at the time of manufacturing the polysilicon by adopting the cooling part (cooling mechanism) for cooling the adjustment member 10 in this manner, it is also possible to prevent the deposition of the polysilicon on the adjustment member 10 and prevent hindrance to the movement of the adjustment member 10. As a result, the adjustment member 10 can be moved without any trouble, and the stress applied to the core wire electrode 60 by the growing polysilicon and the polysilicon in the cooling step in which the growth is completed can be relaxed. For this reason, it is possible to prevent cracking or collapse of the polysilicon during growth or post-manufacturing cooling. The heating step for stress relaxation may be performed after the growth is completed. The adjustment member 10 can also be moved without any trouble at this time, so that the stress applied to the core wire electrode 60 can be relaxed.

The adjustment member 10 may be made of a material different from the material of the silicon core wire electrode 60. As an example, metal is used for the silicon core wire electrode 60, and the same metal can be used for the adjustment member 10, or different kinds of metals, carbon, or other materials that can be energized can be used.

The adjustment member 10 may have a resistivity lower than that of the silicon core wire electrode 60 provided in the silicon core wire electrode 60. Adopting such an aspect is advantageous in that extra heat generation can be avoided.

In a case where the adjustment member 10 does not have the cooling part (cooling mechanism) according to the present embodiment, the temperature of the adjustment member 10 exceeds 400° C. at the time of deposition of the polysilicon, and the polysilicon is deposited on the adjustment member 10. On the other hand, by adopting the cooling part described in the present embodiment, the temperature of the adjustment member 10 can be 400° C. or lower, preferably 350° C. or lower, and more preferably 200° C. or lower, and the deposition of polysilicon on the adjustment member 10 can be prevented. A thermometer 90 for measuring the temperature of the adjustment member 10 may be installed in the adjustment member 10, and the control unit 50 may control the temperature at which the cooling part cools the adjustment member 10 in response to the measurement result in the thermometer 90 (see FIG. 8). Note that the control unit 50 can communicate with other members such as the liquid supply unit 40 and the gas supply unit 25 in addition to the thermometer 90, and can control the liquid supply unit 40, the gas supply unit 25, and the like.

For example, in a case where the generation state of the popcorn and the shape of the grown rod are not desired as a result of growing in the structure in which the adjustment member 10 is disposed immediately above the through hole of the silicon core wire electrode 60, the arrangement can be adjusted to solve the problem and desired polysilicon can be obtained by growing when the device including the adjustment member 10 is adopted.

### <Method>

An example of a method for manufacturing a polysilicon rod using an apparatus for manufacturing a polysilicon rod will be described.

By applying a current to the silicon core wire electrode 60, polysilicon is deposited on the silicon core wire 1. At this time, the silane source gas is supplied from the supply gas inlet 91 of the source gas supply unit, and the silane source gas that has not been used for the growth of polysilicon is discharged from the exhaust gas outlet 96.

In the step of depositing polysilicon in this manner, the adjustment member 10 is cooled by the cooling part. At this time, any one or more or all of a mechanism that blows a cooling gas from a nozzle toward the adjustment member 10 as illustrated in FIG. 6, a mechanism that cools the adjustment member 10 by a heat dissipation effect by connecting the adjustment member to the bottom plate 80 via the heat dissipation insulating member 30 as illustrated in FIGS. 5 and 6, and a mechanism that indirectly cools the adjustment member 10 by a coolant may be used.

In order to relax the stress when the diameter of the polysilicon increases or when the polysilicon rod is cooled, the adjustment member 10 naturally moves in the plane. By adopting the cooling part (cooling mechanism) described in the present embodiment, the silicon core wire 1 smoothly moves with respect to the bottom plate 80. That is, by adopting the cooling part described in the present embodiment, deposition of silicon crystals on the adjustment member 10 can be prevented, and as a result, adjustment by the adjustment member 10 can be smoothly performed.

In addition, a step of generating a next polysilicon rod (new polysilicon rod) is performed after the grown polysilicon rod is removed, but it may be necessary to adjust and move the position of the adjustment member 10 before the next polysilicon is grown. According to the present embodiment, deposition of silicon crystals on the adjustment member 10 can be prevented. Therefore, when the position of the adjustment member 10 is adjusted and moved in this manner, it is possible to prevent the crystals deposited on the adjustment member 10 from falling into the furnace and becoming contaminated at the time of adjustment by the adjustment member 10, and it is also possible to prevent occurrence of a problem that adjustment by the adjustment member 10 cannot be performed smoothly.

According to the present embodiment, the silicon core wire 1 can be installed at an optimum position in the reaction furnace 100, and it is possible to grow the polysilicon in the desired manner according to the installation. In the growth process of the polysilicon, the position of the silicon core wire 1 can be moved (adjusted) without any trouble in order to relax the stress generated in the polysilicon.

1. An apparatus for manufacturing a polysilicon rod comprising:
a core wire on which polysilicon is deposited;
a core wire electrode provided to penetrate a bottom plate;
an adjustment member provided between the silicon core wire and the core wire electrode, and movable with respect to the bottom plate; and
a cooling part capable of cooling the adjustment member.

2. The apparatus for manufacturing a polysilicon rod according to claim 1, wherein the cooling part has a nozzle that blows gas toward the adjustment member.

3. The apparatus for manufacturing a polysilicon rod according to claim 2, wherein the gas is a silane source gas.

4. The apparatus for manufacturing a polysilicon rod according to claim 1, wherein the cooling part has a heat dissipation insulating member provided between the bottom plate and the adjustment member and configured to cool the adjustment member via the bottom plate.

5. The apparatus for manufacturing a polysilicon rod according to claim 1, wherein the cooling part is provided in the core wire electrode and has a flow path through which a coolant flows.

6. The apparatus for manufacturing a polysilicon rod according to claim 1, wherein the adjustment member connects the core wire electrode and the silicon core wire so that a central axis of the core wire electrode is different from a central axis of the silicon core wire.

7. The apparatus for manufacturing a polysilicon rod according to claim 1, wherein the adjustment member is made of a material different from a material of the core wire electrode.

8. The apparatus for manufacturing a polysilicon rod according to claim 1, wherein the adjustment member has a resistivity lower than a resistivity of the core wire electrode.

9. The apparatus for manufacturing a polysilicon rod according to claim 1, wherein the cooling part has
a nozzle that blows gas toward the adjustment member,
a heat dissipation insulating member provided between the bottom plate and the adjustment member and configured to cool the adjustment member via the bottom plate, and
a flow path that is provided in the core wire electrode and through which a coolant flows.

10. A method for manufacturing a polysilicon rod using the apparatus for manufacturing a polysilicon rod according to claim 1, the method comprising
a step of depositing the polysilicon on the core wire,
wherein the step of depositing the polysilicon includes cooling an adjustment member by the cooling part.
